(19) United States
(12) Patent Application Publication
(10) Pub. No.: US 2026/0268636 A1
(43) Pub. Date: Sep. 10, 2026

(54) METHOD FOR EXTRACTING ZGV FEATURES BASED ON LOCAL ENTROPY RECONSTRUCTION-OPTIMIZED MULTI-SYNCHROSQUEEZING TRANSFORM ALGORITHM

(71) Applicant: Harbin Institute of Technology, Harbin City (CN)

(72) Inventors: Bo Zhao, Harbin City (CN); Yichao Tang, Harbin City (CN); Xinqi Tian, Harbin City (CN); Tianchen Sheng, Harbin City (CN); Jiaxin Li, Harbin City (CN)

(21) Appl. No.: 19/345,202

(22) Filed: Sep. 30, 2025

(30) Foreign Application Priority Data
Mar. 4, 2025 (CN) 202510248262.8

(51) Int. Cl. G06V 10/62; G06F 17/14; G06V 10/52

(52) U.S. Cl. CPC G06V 10/62; G06F 17/148; G06V 10/52

(57) ABSTRACT

Disclosed is a method for extracting ZGV features based on a local entropy reconstruction-optimized multi-synchrosqueezing transform algorithm, specifically including the following steps: S1: acquiring a to-be-processed signal with time-varying features and performing a short-time Fourier transform; S2: estimating an instantaneous frequency corresponding to a result of the short-time Fourier transform; S3: performing a synchrosqueezing transform; S4: iterating a result of the synchrosqueezing transform; S5: performing Renyi entropy calculation and reconstruction accuracy calculation on a transform result, and evaluating the transform result; S6: constructing a Bayesian cost function, and performing Bayesian optimization on the cost function to obtain a globally optimized window function length; and S7: applying the globally optimized window function length to a Gaussian window function to generate a new Gaussian window function, and executing the short-time Fourier transform on the original signal with the time-varying features to obtain a time-frequency image of the ZGV features.

### TECHNICAL FIELD

This disclosure relates to a method for extracting ZGV features and, in particular, to a method for extracting ZGV features based on a local entropy reconstruction-optimized multi-synchrosqueezing transform algorithm in the technical field of signal feature extraction.

### BACKGROUND

With the continuous advancement of the aviation industry, increasingly stringent requirements have been placed on the performance and service life of aircraft. Accurately monitoring stress distribution and damage defects in aircraft panels is crucial for preventing structural failures, monitoring airframe fatigue damage, and extending service life, and is also a highly challenging and significant task. In recent years, mechanical property measurement methods based on zero-group-velocity (ZGV) Lamb waves have gradually become a research hotspot due to their high sensitivity and high-resolution characteristics, and are expected to develop into a new generation of high-precision structural health monitoring technology.

Based on the characteristics of ZGV Lamb waves, researchers have developed a series of measurement techniques. For example, Liu Bin et al. proposed a method for detecting defects in honeycomb structures based on ZGV feature analysis in the patent numbered CN116735712A. This method achieves relatively precise detection of defects in honeycomb structures by comparing the theoretical ZGV frequency distribution in a defect-free state with the local ZGV frequency distribution at actual measurement points. However, this method does not delve into the specific algorithms and processes for ZGV frequency extraction, which is one of the key reasons why the accuracy of defect detection is difficult to further improve. Therefore, to further improve the accuracy and reliability of defect detection, there is an urgent need to develop more accurate ZGV feature extraction techniques.

Both existing theoretical simulations and experimental results indicate that ZGV waves are non-stationary signals. A simple Fourier transform has certain limitations in extracting their features. In the industrial field, bearing fault signals are also a common type of non-stationary signal. Liao Shuming et al. proposed a rolling bearing fault diagnosis method based on a synchrosqueezing transform (SST) and an improved CMT model in the patent numbered CN118395081A. The method proposed by Liao Shuming et al. first uses SST to extract time-frequency information from rolling bearings, then trains an improved convolutional neural networks meets visual transformers (CMT) model, and finally inputs time-frequency information of on-site collected bearing vibration signals into the model to achieve real-time fault diagnosis. Although this method is suitable for extracting non-stationary signals in rotating machinery bearings, the frequency of ZGV signals is typically in the megahertz range, which is much higher than the kilohertz range corresponding to bearing faults; additionally, this method requires a large training dataset, and collecting training data in the emerging field of ZGV measurement is relatively difficult. For these reasons, it can be concluded that existing mature algorithms (such as SST) should be further improved to address the characteristics of ZGV measurement.

For the analysis of non-stationary signals, a time-frequency image is commonly used for visual representation. Short-time Fourier transform (STFT), as a classical time-frequency analysis method, along with its subsequent developments such as synchrosqueezing transform (SST), can effectively characterize the time-frequency information of signals. However, these methods have certain limitations when processing ZGV signals. Specifically, the time-frequency image extracted by STFT exhibits severe energy leakage, leading to inaccurate representation of ZGV signal frequencies, showing fluctuations of approximately 0.1 MHz. This level of error is unacceptable for high-precision mechanical property measurements. Although SST and second-order SST have somewhat mitigated this issue and can demonstrate the trend of frequency variation over time, significant energy leakage still persists. Additionally, the conventional synchrosqueezing transform (SST) method relies on manually set time windows, and the selection of the time window directly affects the accuracy of the transform results. Moreover, manually adjusting time window parameters is not only time-consuming but also lacks an objective evaluation standard for the quality of the extraction results.

### SUMMARY

To address the issue of limited accuracy in ZGV-based measurement techniques caused by insufficient accuracy in ZGV feature extraction, this disclosure aims to achieve more accurate and reliable feature extraction of ZGV signals. Accordingly, a method for extracting ZGV features based on a local entropy reconstruction-optimized multi-synchrosqueezing transform algorithm is proposed.

The technical solution adopted by this disclosure to address the aforementioned issues is as follows:
a method for extracting ZGV features based on a local entropy reconstruction-optimized multi-synchrosqueezing transform algorithm, where the method is implemented through the following steps:
S1: a computer acquires a to-be-processed signal with time-varying features and performs a short-time Fourier transform on the to-be-processed signal to obtain a preliminary short-time Fourier transform result;
S2: based on the short-time Fourier transform result from the step S1, the computer estimates an instantaneous frequency corresponding to the short-time Fourier transform result;
S3: the computer inputs the instantaneous frequency estimated in the step S2 and the short-time Fourier transform result from the step S1 into a synchrosqueezing transform process, and performs time-squeezing reassignment to obtain a synchrosqueezing transform result;
S4: the computer performs iterative processing on the synchrosqueezing transform result from the step S3 until a preset convergence condition is met, and outputs a final iteration result;
S5: the computer performs Renyi entropy calculation and reconstruction accuracy calculation respectively on the final iteration result from the step S4 to obtain a Renyi entropy value and reconstruction accuracy for evaluating the transform result;
S6: the computer constructs a Bayesian cost function using the Renyi entropy value and reconstruction accuracy from the step S5, and performs Bayesian optimization on the Bayesian cost function to obtain a globally optimized window function length; and
S7: the computer applies the globally optimized window function length from the step S6 to a Gaussian window function to generate a new Gaussian window function, re-executes the short-time Fourier transform on the original signal with the time-varying features using the new window function, and outputs a time-frequency image of the ZGV features.

Further, the step S1 specifically includes:
assuming a square-integrable signal:

$$x ( t ) = A ( t ) {e}^{i φ ( t )} , \qquad ( 1 )$$

windowing the signal using a square-integrable even real window function g(t), with the short-time Fourier transform as follows:

$$G ( t , ω ) = {\int }_{- ∞}^{+ ∞} x ( u ) g ( u - t ) {e}^{- i ω ( u - t )} du ; \qquad ( 2 )$$

where assuming that an amplitude A(t) and phase φ(t) of x(t)=A(t)e^{iφ(t)} change sufficiently slowly within a studied time interval, higher-order terms in a Taylor expansion are ignored, o(A′(t)) and o(φ″(t)) are ignored, it is approximated that:

$$\{ \begin{matrix}A ( u ) = A ( t ) \\ φ ( u ) = φ ( t ) + {φ}^{′} ( t ) ( u - t )\end{matrix} ; \qquad ( 3 )$$

by substituting the equation (3) into the equation (2), it yields:

$$\begin{matrix}G ( t , ω ) = A ( t ) {e}^{i φ ( t )} {\int }_{- ∞}^{+ ∞} g ( u - t ) {e}^{i ( {φ}^{′} ( t ) ( u - t ) ) - i ω ( u - t )} d ( u - t ) \\ = A ( t ) {e}^{i φ ( t )} \hat{g} ( ω - {φ}^{′} ( t ) )\end{matrix} ; \qquad ( 4 )$$

where in the equation (4), ĝ(ω-φ′(t)) represents a Fourier transform of the window function with respect to ω-φ′(t).

Further, the step S2 specifically includes:
taking a partial derivative with respect to time t of the obtained result of the short-time Fourier transform under the approximated condition, with o(A′(t)) and o(φ″(t)) ignored, meaning A(t) and φ′(t) are approximately considered constants, where the partial derivative under the approximated condition is as follows:

$$\begin{matrix}{\partial }_{t} \tilde{G} ( t , ω ) = {\partial }_{t} ( A ( t ) {e}^{i φ ( t )} \hat{g} ( ω - {φ}^{′} ( t ) ) ) \\ = A ( t ) {e}^{i φ ( t )} \hat{g} ( ω - {φ}^{′} ( t ) ) i {φ}^{′} ( t ) \\ = G ( t , ω ) i {φ}^{′} ( t )\end{matrix} ; \qquad ( 5 )$$

constructing an instantaneous frequency estimation formula to estimate the instantaneous frequency corresponding to the result of the short-time Fourier transform:

$$\hat{ω} ( t , ω ) = \frac{{\partial }_{t} \tilde{G} ( t , ω )}{i G ( t , ω )} ; \qquad ( 6 )$$

where by substituting the equation (5) into the equation (6), it yields:

$$\hat{ω} ( t , ω ) = {φ}^{′} ( t ) = \frac{d φ ( t )}{dt} = ω . \qquad ( 7 )$$

Further, the step S3 specifically includes:
performing the synchrosqueezing transform using the estimated instantaneous frequency \hat{ω}(t,ω) and the result G(t,ω) of the short-time Fourier transform to achieve the time-squeezing reassignment, thereby concentrating energy of ZGV Lamb waves:

$$Ts ( t , η ) = {\int }_{- ∞}^{+ ∞} G ( t , ω ) δ ( η - \hat{ω} ( t , ω ) ) d ω ; \qquad ( 8 )$$

where in the equation (8), η represents a frequency corresponding to a result of the synchrosqueezing transform.

Further, the iteration processing in the step S4 is specifically expressed as follows:
assuming that Ts(t,η)=Ts^{[1]}(t,η), an iteration process is as follows:

$$\begin{matrix}{Ts}^{[ 2 ]} ( t , η ) = {\int }_{- ∞}^{+ ∞} {Ts}^{[ 1 ]} ( t , ω ) δ ( η - \hat{ω} ( t , ω ) ) d ω \\ {Ts}^{[ 3 ]} ( t , η ) = {\int }_{- ∞}^{+ ∞} {Ts}^{[ 2 ]} ( t , ω ) δ ( η - \hat{ω} ( t , ω ) ) d ω \\ ⋮ \\ {Ts}^{[ N ]} ( t , η ) = {\int }_{- ∞}^{+ ∞} {Ts}^{[ N - 1 ]} ( t , ω ) δ ( η - \hat{ω} ( t , ω ) ) d ω\end{matrix} ; \qquad ( 9 )$$

where a difference between a current result and a previous result is calculated and, when the difference is less than a convergence threshold or when a maximum number of iterations is reached, the transform result is obtained.

Further, the Renyi entropy calculation in the step S5 specifically includes:
to evaluate a degree of energy concentration in the transform result, calculating a local Renyi entropy

$${RE}_{l}^{β} ( ϑ ) :$$

$${RE}_{l}^{β} ( ϑ ) = \frac{1}{1 - λ} {log}_{2} ( {\int }_{l} {\int }_{φ}^{φ + 2 β} {( \frac{\vert {Ts}^{[ N ]} ( σ , ν ) \vert}{{\int }_{l} {\int }_{ϑ}^{ϑ + 2 β} \vert {Ts}^{[ N ]} ( σ , ν ) \vert d σ d ν} )}^{λ} d σ d ν ) ; \qquad 10 )$$

where in the equation (10), ϑ represents time; β represents a size of an interval around the time ϑ; and λ represents an order of the Rényi entropy, set to Δ=3.

Further, the reconstruction accuracy calculation in the step S5 specifically includes:
calculating a local reconstruction quality factor RQF

$$R \tilde{Q} {F}_{l}^{β} ( ϑ ) :$$

$$R \tilde{Q} {F}_{l}^{β} ( ϑ ) = 10 {log}_{10} ( \frac{{‖ {x}_{β} ( ϑ ) ‖}^{2}}{{‖ {x}_{β} ( ϑ ) - {\hat{x}}_{β} ( ϑ ) ‖}^{2}} ) ; \qquad ( 11 )$$

$$where$$

$${x}_{β} ( ϑ ) = [ x ( ϑ ) , x ( ϑ + 1 ) , … , x ( ϑ + 2 β ) ] ,$$

\hat{x}_{β}(ϑ)=[\hat{x}(ϑ),\hat{x}(ϑ+1), . . . ,\hat{x}(ϑ+2β)], and \hat{x}(t) represent reconstructed signals obtained via an inverse Fourier transform of Ts_{[N]}(t,η).

Further, the Bayesian cost function constructed in the step S6 is expressed as follows:

$$g ( l ( ϑ ) ) = 1 - \frac{R \tilde{Q} {F}_{l}^{β} ( ϑ )}{{RE}_{l}^{β} ( ϑ )} . \qquad ( 12 )$$

Further, the Bayesian optimization performed on the Bayesian cost function in the step S6 is expressed as follows

$${l}^{*} ( ϑ ) = arg {min}_{l ∈ [ {l}_{m i n} , {l}_{m ax} ]} g ( l ) ; \qquad ( 13 )$$

where in the equation (13), l*(ϑ) represents the globally optimized window function length.

Further, in the step S7, the applying the globally optimized window function length from the step S6 to the Gaussian window function to generate the new Gaussian window function is expressed as follows:

$${g}_{L ( m )} ( t ) = \frac{1}{L ( m )} g ( \frac{t}{L ( m )} ) ; \qquad ( 14 )$$

where in the equation (14),

$$g ( t ) = \frac{1}{\sqrt{2 π}} {e}^{- \frac{{t}^{2}}{2}} .$$

This disclosure has the following beneficial effects:
1. This disclosure constructs a cost function based on energy concentration and signal reconstruction accuracy for Bayesian optimization, enabling the acquisition of a globally optimal window function length. This significantly reduces energy leakage in the extraction of ZGV wave signals and mitigates the phenomenon of energy leakage in signal feature extraction.
2. This disclosure enhances the accuracy and clarity of spectral estimation by reassigning energy from the short-time Fourier transform (STFT) spectrogram to more accurate time-frequency locations. Furthermore, it automatically generates optimization results by comparing the original signal with the reconstructed signal, reduces the number of parameters requiring manual adjustment by users, simplifies the algorithm's operational workflow, improves efficiency, and is applicable to various scenarios for extracting features from weak non-stationary signals.

### BRIEF DESCRIPTION OF THE DRAWINGS

FIG. 1 is a schematic flowchart of a method for extracting ZGV features based on a local entropy reconstruction-optimized multi-synchrosqueezing transform algorithm according to this disclosure;

FIG. 2 is a schematic diagram of ZGV frequencies at different time periods of the same signal;

FIG. 3 is a schematic diagram of frequency-wavenumber dispersion curves for a 3-mm-thick 6061 aluminum alloy plate;

FIG. 4 is a schematic diagram of time-frequency images of a non-stationary signal;

FIG. 5 is a schematic diagram of processing results for a signal containing noise; and

FIG. 6 is a schematic diagram of a time-frequency image obtained after processing a signal segment according to this disclosure.

### DETAILED DESCRIPTION OF THE EMBODIMENTS

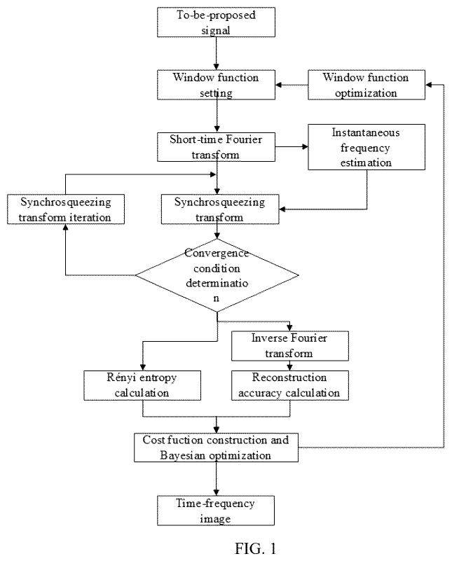

Embodiment I: with reference to FIGS. 1-6, this embodiment describes a method for extracting ZGV features based on a local entropy reconstruction-optimized multi-synchrosqueezing transform algorithm, which is implemented through the following steps:

S1: a computer acquires a to-be-processed signal with time-varying features and performs a short-time Fourier transform on the to-be-processed signal to obtain a preliminary short-time Fourier transform result;
where assuming a square-integrable signal:

$$x ( t ) = A ( t ) {e}^{i φ ( t )} , \qquad ( 1 )$$

the signal is windowed using a square-integrable even real window function g(t), with the short-time Fourier transform as follows:

$$G ( t , ω ) = {\int }_{- ∞}^{+ ∞} x ( u ) g ( u - t ) {e}^{- i ω ( u - t )} du ; \qquad ( 2 )$$

assuming that an amplitude A(t) and phase φ(t) of x(t)=A(t)e^{iφ(t)} change sufficiently slowly within a studied time interval, higher-order terms in a Taylor expansion are ignored, and o(A′(t)) o(φ″(t)) are ignored, it is approximated that:

$$\{ \begin{matrix}A ( u ) = A ( t ) \\ φ ( u ) = φ ( t ) + {φ}^{′} ( t ) ( u - t )\end{matrix} ; \qquad ( 3 )$$

by substituting the equation (3) into the equation (2), it yields:

$$\begin{matrix}G ( t , ω ) = A ( t ) {e}^{i φ ( t )} {\int }_{- ∞}^{+ ∞} g ( u - t ) {e}^{i ( {φ}^{′} ( t ) ( u - t ) ) - i ω ( u - t )} d ( u - t ) \\ = A ( t ) {e}^{i φ ( t )} \hat{g} ( ω - {φ}^{′} ( t ) )\end{matrix} ; \qquad ( 4 )$$

where in the equation (4), ĝ(ω-φ′(t)) represents a Fourier transform of the window function with respect to ω-φ′(t).

S2: based on the short-time Fourier transform result from the step S1, the computer estimates an instantaneous frequency corresponding to the short-time Fourier transform result;
where a partial derivative is taken with respect to time t of the obtained result of the short-time Fourier transform under the approximated condition, with o(A′(t)) and o((φ″(t)) ignored, meaning A(t) and φ′(t) are approximately considered constants, where the partial derivative under the approximated condition is as follows:

$$\begin{matrix}{\partial }_{t} \tilde{G} ( t , ω ) = {\partial }_{t} ( A ( t ) {e}^{i φ ( t )} \hat{g} ( ω - {φ}^{′} ( t ) ) ) \\ = A ( t ) {e}^{i φ ( t )} \hat{g} ( ω - {φ}^{′} ( t ) ) i {φ}^{′} ( t ) \\ = G ( t , ω ) i {φ}^{′} ( t )\end{matrix} ; \qquad ( 5 )$$

an instantaneous frequency estimation formula is constructed to estimate the instantaneous frequency corresponding to the result of the short-time Fourier transform:

$$\hat{ω} ( t , ω ) = \frac{{\partial }_{t} \tilde{G} ( t , ω )}{i G ( t , ω )} ; \qquad ( 6 )$$

where by substituting the equation (5) into the equation (6), it yields:

$$\hat{ω} ( t , ω ) = {φ}^{′} ( t ) = \frac{d φ ( t )}{dt} = ω . \qquad ( 7 )$$

It can be seen that the constructed estimation formula is reasonable.

S3: the computer inputs the instantaneous frequency estimated in the step S2 and the short-time Fourier transform result from the step S1 into a synchrosqueezing transform process, and performs time-squeezing reassignment to obtain a synchrosqueezing transform result;
where the synchrosqueezing transform is performed using the estimated instantaneous frequency \hat{ω}(t,ω) and the result G(t,ω)) of the short-time Fourier transform to achieve the time-squeezing reassignment, thereby concentrating energy of ZGV Lamb waves:

$$Ts ( t , η ) = {\int }_{- ∞}^{+ ∞} G ( t , ω ) δ ( η - \hat{ω} ( t , ω ) ) d ω ; \qquad ( 8 )$$

where in the equation (8), η represents a frequency corresponding to a result of the synchrosqueezing transform.

S4: the computer performs iterative processing on the synchrosqueezing transform result from the step S3, i.e., iterating a result of the equation (8), until a preset convergence condition is met, and outputs a final iteration result;
where assuming that Ts(t,η)=Ts^{[1]}(t,η), an iteration process is as follows:

$$\begin{matrix}{Ts}^{[ 2 ]} ( t , η ) = {\int }_{- ∞}^{+ ∞} {Ts}^{[ 1 ]} ( t , ω ) δ ( η - \hat{ω} ( t , ω ) ) d ω \\ {Ts}^{[ 3 ]} ( t , η ) = {\int }_{- ∞}^{+ ∞} {Ts}^{[ 2 ]} ( t , ω ) δ ( η - \hat{ω} ( t , ω ) ) d ω \\ ⋮ \\ {Ts}^{[ N ]} ( t , η ) = {\int }_{- ∞}^{+ ∞} {Ts}^{[ N - 1 ]} ( t , ω ) δ ( η - \hat{ω} ( t , ω ) ) d ω\end{matrix} ; \qquad ( 9 )$$

where a difference between a current result and a previous result is calculated and, when the difference is less than a convergence threshold or when a maximum number of iterations is reached, the transform result is obtained.

S5: the computer performs Renyi entropy calculation and reconstruction accuracy calculation respectively on the final iteration result from the step S4 to obtain a Renyi entropy value and reconstruction accuracy for evaluating the transform result;
where calculating the Renyi entropy specifically includes:
to evaluate a degree of energy concentration in the transform result, calculating a local Rényi entropy

$$\text{?} ( ϑ ) :$$

$$\text{?} ( ϑ ) = \frac{1}{1 - λ} {log}_{2} ( {\int }_{R} {\int }_{ϑ}^{ϑ + 2 β} {( \frac{\vert {Ts}^{[ N ]} ( σ , ν ) \vert}{{\int }_{R} {\int }_{ϑ}^{ϑ + 2 β} \vert {Ts}^{[ N ]} ( σ , ν ) \vert d σ d ν} )}^{λ} d σ d ν ) ; \qquad 10 )$$

where in the equation (10), ϑ represents time; β represents a size of an interval around the time ϑ; and λ represents an order of the Renyi entropy, typically set to λ=3.
where calculating the reconstruction accuracy specifically includes:
calculating a local reconstruction quality factor

$$R \tilde{Q} {F}_{l}^{β} ( ϑ ) :$$

$$R \tilde{Q} {F}_{l}^{β} ( ϑ ) = 10 {log}_{10} ( \frac{{‖ {x}_{β} ( ϑ ) ‖}^{2}}{{‖ {x}_{β} ( ϑ ) - {\hat{x}}_{β} ( ϑ ) ‖}^{2}} ) ; \qquad ( 11 )$$

wherein x_{β}(ϑ)=[x(ϑ),x(ϑ+1), . . . ,x(ϑ+2β)]\hat{x}_{β}(ϑ)=[\hat{x}(ϑ),\hat{x}(ϑ+1), . . . ,\hat{x}(ϑ+2β)], and \hat{x}(t) represent reconstructed signals obtained via an inverse Fourier transform of Ts[^{N}](t,η).

S6: the computer constructs a Bayesian cost function using the Renyi entropy value and reconstruction accuracy from the step S5, and performs Bayesian optimization on the Bayesian cost function to obtain a globally optimized window function length;
where the Bayesian cost function is constructed using the equations (11) and (12), and is expressed as follows:

$$g ( l ( ϑ ) ) = 1 - \frac{R \tilde{Q} {F}_{l}^{β} ( ϑ )}{{RE}_{l}^{β} ( ϑ )} ; \qquad ( 12 )$$

the Bayesian optimization of the cost function is expressed as follows:

$${l}^{*} ( ϑ ) = arg {min}_{l ∈ [ {l}_{m i n} , {l}_{ma x} ]} g ( l ) ; \qquad ( 13 )$$

where in the equation (13), l*(8) represents the globally optimized window function length.

S7: the computer applies the globally optimized window function length from the step S6 to a Gaussian window function to generate a new Gaussian window function, re-executes the short-time Fourier transform on the original signal with the time-varying features using the new window function, and outputs a time-frequency image of the ZGV features.
where the new window function is obtained by using the globally optimized window function length as the window length of the Gaussian window function, that is, the new window function is obtained by using a result of the equation (13) as the window length of the Gaussian window function, and the new window function is expressed as follows:

$${g}_{L ( m )} ( t ) = \frac{1}{L ( m )} g ( \frac{t}{L ( m )} ) ; \qquad ( 14 )$$

where in the equation (14),

$$g ( t ) = \frac{1}{\sqrt{2 π}} {e}^{- \frac{{t}^{2}}{2}} .$$

Subsequently, the equation (14) expressing the new window function is substituted into the equation (4) to perform a new operation, ultimately obtaining the high-precision time-frequency image that fully characterizes non-stationary characteristics of the signal. This ensures results with a higher signal reconstruction quality factor (RQF) and a lower Renyi entropy value.

This disclosure aims to achieve precise extraction of ZGV features. For this purpose, the adopted method should not only accurately reflect the non-stationary characteristics of ZGV signals but also possess good noise identification capabilities to facilitate subsequent signal identification and elimination.

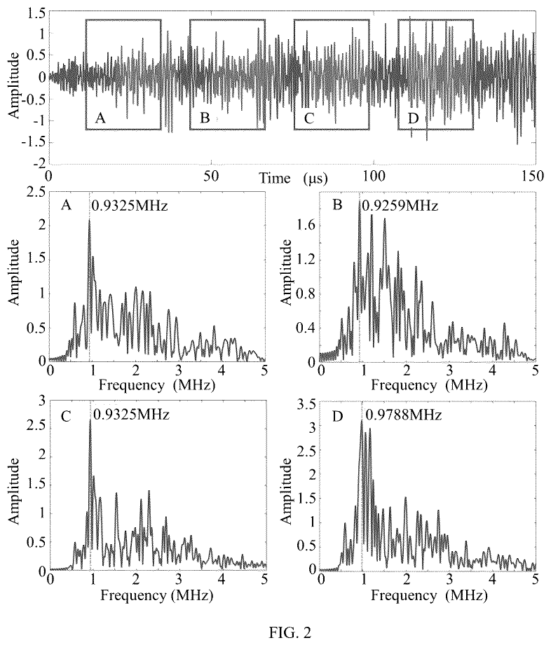

Zero-group-velocity (ZGV) Lamb waves exhibit non-stationary characteristics. When segmenting the same signal and performing Fourier transforms separately, significant differences in ZGV frequencies across different time segments can be observed, as shown in FIG. 2. Therefore, accurately characterizing the dynamic time-varying properties of ZGV signals is a crucial prerequisite for analyzing and precisely extracting ZGV signal features.

Theoretical analysis:

For a thin plate made of an isotropic elastic material, the relationship between frequency f and wavenumber k can be characterized by the following dispersion equation according to the Rayleigh-Lamb frequency equation:

$$( {q}^{2} - {k}^{2} ) tan ( qh ) tan ( p h ) = 4 {k}^{2} qp \\ p = \sqrt{{( \frac{2 π f}{{c}_{L}} )}^{2} - {k}^{2}} , q = \sqrt{{( \frac{2 π f}{{c}_{T}} )}^{2} - {k}^{2}} . \qquad ( 15 )$$

In the equation (15), f represents the guided wave frequency; h represents the half-thickness of the plate; k represents the wavenumber; and c_{L} and C_{T} represent the longitudinal and transverse wave velocities, respectively.

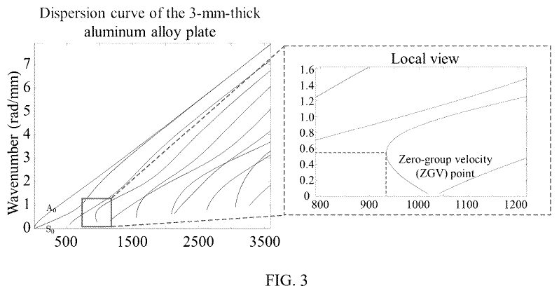

Taking a 3-mm-thick 6061 aluminum alloy plate as an example, its dispersion curves calculated using the equation (15) are shown in FIG. 3. A local minimum value of frequency can be observed in the left region of FIG. 3, with a magnified view of this local minimum value provided on the right side of FIG. 3. As shown, the interference between the forward waveguide of the S1 mode and the backward waveguide of the S2b mode in space generates S1 mode ZGV Lamb waves. The S1 mode curve exhibits points where the derivative of angular frequency with respect to wavenumber becomes zero. According to the group velocity formula, it can be derived that:

$${v}_{g} = \frac{d ω}{dk} = 0 ; \qquad ( 16 )$$

where in the equation (16), v_{g} represents the group velocity; ω represents the angular frequency; and k represents the wavenumber. At the local minimum value of frequency, the group velocity becomes zero, resulting in the generation of ZGV Lamb waves in the plate.

Simulation and experimental results indicated that ZGV Lamb waves exhibited time-varying features in their time-frequency properties, with their frequency undergoing slight changes over time. This posed interference for the feature extraction of ZGV Lamb waves.

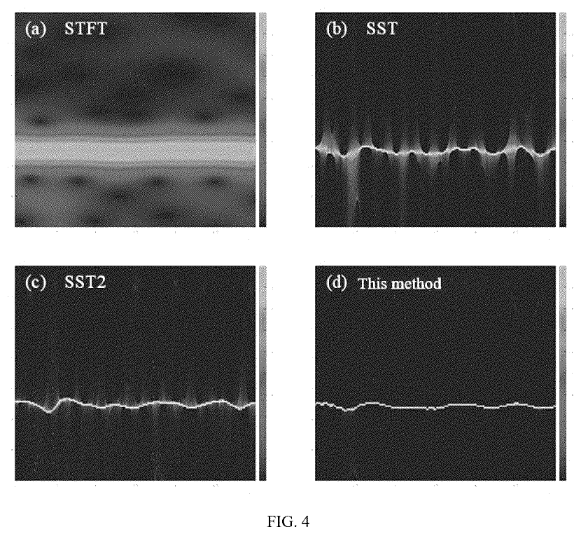

As shown in FIG. 4, for the analysis of non-stationary signals, a time-frequency image was used for visual representation. The time-domain signal was processed using a short-time Fourier transform, with the ZGV Lamb wave frequency approximately at 1 MHz. FIG. 4A shows the processing results of the short-time Fourier transform (STFT), revealing that energy is concentrated within ±0.1 MHz of the theoretical ZGV frequency, which would cause great fluctuations in the extracted ZGV frequency; the time-frequency image extracted by STFT exhibits severe energy leakage, leading to inaccurate representation of the ZGV signal frequency, showing fluctuations of approximately ±0.1 MHz. This level of error is unacceptable for high-precision mechanical property measurements. FIG. 4B shows the processing results of the synchrosqueezing transform (SST), and FIG. 4C shows the processing results of second-order SST. Although SST and second-order SST have somewhat mitigated this issue and can demonstrate the trend of frequency variation over time, significant energy leakage still persists. FIG. 4D shows the processing results of this disclosure, where a substantial improvement in energy concentration can be observed.

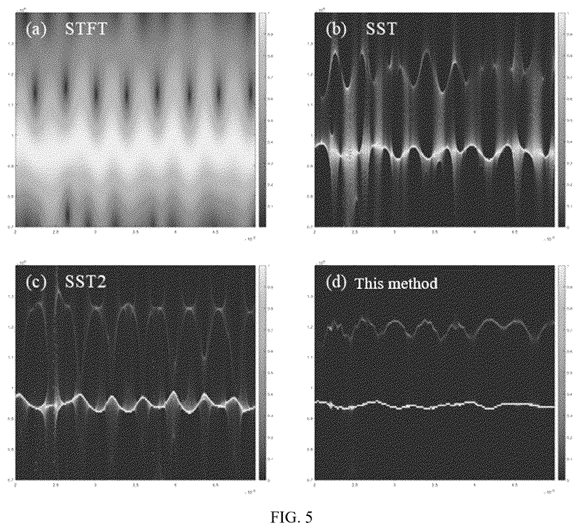

As shown in FIG. 5, signals containing noise were processed to test the signal resolution capability of the algorithm.

The normalized expression of noise was as follows:

$$y = sin ( 2 π \times 1 MHz \times ( t + 0.2 \times sin ( t ) ) ) . \qquad ( 17 )$$

FIG. 5A shows the processing results of STFT for the signals containing noise, where noise and ZGV signals cannot be distinguished; FIG. 5B and FIG. 5C show the processing results of SST and second-order SST for the signals containing noise, respectively; FIG. 5D shows the processing results of this disclosure, successfully distinguishing the ZGV signal (yellow curve) from noise (light blue curve). When processing signals containing noise with frequencies close to that of a ZGV signal, the algorithm proposed in this disclosure also demonstrated superior performance, successfully distinguishing signal components from noise components.

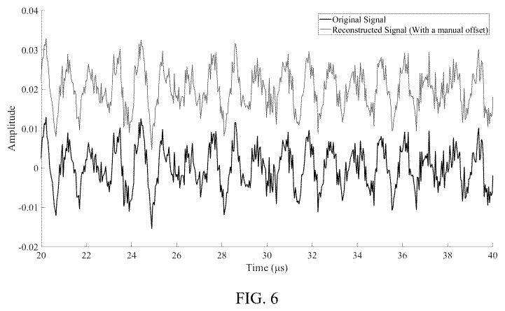

As shown in FIG. 6, a time-frequency image was obtained by processing a signal segment using the local entropy reconstruction-optimized multi-synchrosqueezing transform algorithm of this disclosure. To validate the effectiveness of the algorithm, the distortion of the time-frequency image was validated: first, an inverse Fourier transform was performed on the time-frequency image to reconstruct the signal; then, the reconstructed signal was compared with the original signal. Experimental results demonstrated that the reconstructed signal highly matched the original signal. This observation indicates that the signal processing algorithm proposed in this disclosure introduces minimal distortion, thereby validating the rationality and effectiveness of the algorithm.

Renyi entropy is a generalized form of classical Shannon entropy. As a generalized entropy measure, it holds important application value in time-frequency analysis. Renyi entropy can quantitatively characterize the concentration or diffusion of signal energy in the time-frequency domain. Specifically, when the signal energy is highly concentrated on the time-frequency plane (e.g., narrowband signals or signals with clear modulation features), the corresponding Renyi entropy value is small; conversely, when the signal energy is diffusely distributed on the time-frequency plane, the Renyi entropy value increases. Therefore, Renyi entropy can quantitatively measure the degree of time-frequency aggregation. In ZGV feature extraction based on time-frequency analysis, when the time-frequency image generated by the algorithm corresponds to a small Renyi entropy value, it reflects a high degree of energy concentration in that time-frequency image, in which case the ZGV information extracted is typically more accurate and reliable compared to that from a time-frequency image with a larger Renyi entropy value.

As shown in the table below, it presents the ZGV frequencies and their standard deviations obtained by various methods, along with the corresponding Renyi entropy values of the time-frequency images. The calculation of the standard deviation of ZGV frequency was based on the weighted average of the time-frequency image, with the weights being the magnitude values of the elements at each frequency point. The standard deviation was quantified using the weighted average standard deviation formula.

| Algorithm | STFT | SST | SST2 | This method |
|---|---|---|---|---|
| ZGV frequency (MHz) | 0.9657 | 0.9461 | 0.9575 | 0.9442 |
| Standard deviation (MHz) | 0.1457 | 0.0674 | 0.0966 | 0.0368 |
| Rényi entropy | 10.8521 | 6.4393 | 6.6505 | 4.3968 |

The results indicate that the Renyi entropy value of this disclosure is significantly lower than those of other methods, and its corresponding standard deviation of ZGV frequency is also the smallest. According to the characteristics of Renyi entropy, a lower entropy value indicates that the energy distribution of the extracted ZGV signal is more concentrated and less diffuse. For the same signal, the method proposed herein achieves a lower Renyi entropy value while ensuring a high signal reconstruction quality factor (RQF), demonstrating its superiority over other methods. It achieves performance superior to conventional time-frequency transform methods, thereby enabling more accurate and reliable feature extraction of ZGV signals. Consequently, based on the above analysis, this method holds advantages in ZGV signal extraction and delivers superior extraction effects.

According to the method for extracting the ZGV features based on the local entropy reconstruction-optimized multi-synchrosqueezing transform algorithm, this disclosure proposes an evaluation criterion based on signal reconstruction quality factor (RQF) and Renyi entropy. Through the Bayesian optimization algorithm, a global search is conducted to determine the optimal time window length for each time point, and the optimization results are iteratively updated into the algorithm. This method enables adaptive selection of the globally optimal time window and performs multi-synchrosqueezing transform, thereby achieving precise extraction of ZGV Lamb wave features.

The foregoing is only illustrative of the exemplary embodiments of this disclosure and constitutes no limitation on this disclosure in any form. Although this disclosure has been illustrated above with exemplary embodiments, such exemplary embodiments are not intended to limit this disclosure, and those skilled in the art can make some changes or modifications to equivalent embodiments with equivalent changes by reference to the technical content disclosed above without departing from the scope of the technical solution of this disclosure. However, any simple modifications, equivalent changes, and improvements made to the above embodiments in accordance with the technical essence, spirit, and principle of this disclosure without departing from the content of the technical solution of this disclosure shall still fall within the protection scope of the technical solution of this disclosure.

What is claimed is:

1. A method for extracting ZGV features based on a local entropy reconstruction-optimized multi-synchrosqueezing transform algorithm, wherein the method is implemented through the following steps:
S1: a computer acquires a to-be-processed signal with time-varying features and performs a short-time Fourier transform on the to-be-processed signal to obtain a preliminary short-time Fourier transform result;
S2: based on the short-time Fourier transform result from the step S1, the computer estimates an instantaneous frequency corresponding to the short-time Fourier transform result;
S3: the computer inputs the instantaneous frequency estimated in the step S2 and the short-time Fourier transform result from the step S1 into a synchrosqueezing transform process, and performs time-squeezing reassignment to obtain a synchrosqueezing transform result;
S4: the computer performs iterative processing on the synchrosqueezing transform result from the step S3 until a preset convergence condition is met, and outputs a final iteration result;
S5: the computer performs Renyi entropy calculation and reconstruction accuracy calculation respectively on the final iteration result from the step S4 to obtain a Renyi entropy value and reconstruction accuracy for evaluating the transform result;
S6: the computer constructs a Bayesian cost function using the Renyi entropy value and reconstruction accuracy from the step S5, and performs Bayesian optimization on the Bayesian cost function to obtain a globally optimized window function length; and
S7: the computer applies the globally optimized window function length from the step S6 to a Gaussian window function to generate a new Gaussian window function, re-executes the short-time Fourier transform on the original signal with the time-varying features using the new window function, and outputs a time-frequency image of the ZGV features.

2. The method for extracting the ZGV features based on the local entropy reconstruction-optimized multi-synchrosqueezing transform algorithm of claim 1, wherein the step S1 specifically comprises:
assuming a square-integrable signal:
$$x ( t ) = A ( t ) {e}^{i φ ( t )} , \qquad ( 1 )$$
windowing the signal using a square-integrable even real window function g(t), with the short-time Fourier transform as follows:
$$G ( t , ω ) = {\int }_{- ∞}^{+ ∞} x ( u ) g ( u - t ) {e}^{- i ω ( u - t )} du ; \qquad ( 2 )$$
wherein assuming that an amplitude A(t) and phase φ(t) of x(t)=A(t)e^{iφ(t)} change sufficiently slowly within a studied time interval, higher-order terms in a Taylor expansion are ignored, and o(A′(t)) and o(φ″(t)) are ignored, it is approximated that:
$$\{ \begin{matrix}A ( u ) = A ( t ) \\ φ ( u ) = φ ( t ) + {φ}^{′} ( t ) ( u - t )\end{matrix} ; \qquad ( 3 )$$
by substituting the equation (3) into the equation (2), it yields:
$$\begin{matrix}G ( t , ω ) = A ( t ) {e}^{i φ ( t )} {\int }_{- ∞}^{+ ∞} g ( u - t ) {e}^{i ( {φ}^{′} ( t ) ( u - t ) ) - i ω ( u - t )} d ( u - t ) \\ = A ( t ) {e}^{i φ ( t )} \hat{g} ( ω - {φ}^{′} ( t ) )\end{matrix} ; \qquad ( 4 )$$
wherein in the equation (4), ĝ(ω-φ′(t)) represents a Fourier transform of the window function with respect to ω-φ′(t).

3. The method for extracting the ZGV features based on the local entropy reconstruction-optimized multi-synchrosqueezing transform algorithm of claim 2, wherein the step S2 specifically comprises:
taking a partial derivative with respect to time t of the obtained result of the short-time Fourier transform under the approximated condition, with o(A′(t)) and o(φ″(t)) ignored, meaning A(t) and φ′(t) are approximately considered constants, wherein the partial derivative under the approximated condition is as follows:
$$\begin{matrix}{\partial }_{t} \tilde{G} ( t , ω ) = {\partial }_{t} ( A ( t ) {e}^{i φ ( t )} \hat{g} ( ω - {φ}^{′} ( t ) ) ) \\ = A ( t ) {e}^{i φ ( t )} \hat{g} ( ω - {φ}^{′} ( t ) ) i {φ}^{′} ( t ) \\ = G ( t , ω ) i {φ}^{′} ( t )\end{matrix} ; \qquad ( 5 )$$
constructing an instantaneous frequency estimation formula to estimate the instantaneous frequency corresponding to the result of the short-time Fourier transform:
$$\hat{ω} ( t , ω ) = \frac{{\partial }_{t} \tilde{G} ( t , ω )}{i G ( t , ω )} ; \qquad ( 6 )$$
wherein by substituting the equation 5 into the equation (6), it yields:
$$\hat{ω} ( t , ω ) = {φ}^{′} ( t ) = \frac{d φ ( t )}{dt} = ω . \qquad ( 7 )$$

4. The method for extracting the ZGV features based on the local entropy reconstruction-optimized multi-synchrosqueezing transform algorithm of claim 3, wherein the step S3 specifically comprises:
performing the synchrosqueezing transform using the estimated instantaneous frequency \hat{ω}(t,ω) and the result G(t,ω) of the short-time Fourier transform to achieve the time-squeezing reassignment, thereby concentrating energy of ZGV Lamb waves:
$$Ts ( t , η ) = {\int }_{- ∞}^{+ ∞} G ( t , ω ) δ ( η - \hat{ω} ( t , ω ) ) d ω ; \qquad ( 8 )$$
wherein in the equation (8), η represents a frequency corresponding to a result of the synchrosqueezing transform.

5. The method for extracting the ZGV features based on the local entropy reconstruction-optimized multi-synchrosqueezing transform algorithm of claim 4, wherein the iteration processing in the step S4 is specifically expressed as follows:
assuming that Ts(t,η)=Ts^{[1]}(t,η), an iteration process is as follows:
$$\begin{matrix}{Ts}^{[ 2 ]} ( t , η ) = {\int }_{- ∞}^{+ ∞} {Ts}^{[ 1 ]} ( t , ω ) δ ( η - \hat{ω} ( t , ω ) ) d ω \\ {Ts}^{[ 3 ]} ( t , η ) = {\int }_{- ∞}^{+ ∞} {Ts}^{[ 2 ]} ( t , ω ) δ ( η - \hat{ω} ( t , ω ) ) d ω \\ ⋮ \\ {Ts}^{[ N ]} ( t , η ) = {\int }_{- ∞}^{+ ∞} {Ts}^{[ N - 1 ]} ( t , ω ) δ ( η - \hat{ω} ( t , ω ) ) d ω\end{matrix} ; \qquad ( 9 )$$
wherein a difference between a current result and a previous result is calculated and, when the difference is less than a convergence threshold or when a maximum number of iterations is reached, the transform result is obtained.

6. The method for extracting the ZGV features based on the local entropy reconstruction-optimized multi-synchrosqueezing transform algorithm of claim 5, wherein the Renyi entropy calculation in the step S5 specifically comprises:
calculating a local Renyi entropy
$${\text{?}}_{l}^{β} ( ϑ )$$
to evaluate a degree of energy concentration in the transform result:
$$\text{?} ( ϑ ) = \frac{1}{1 - λ} {log}_{2} ( {\int }_{R} {\int }_{ϑ}^{ϑ + 2 β} {( \frac{\vert {Ts}^{[ N ]} ( σ , ν ) \vert}{{\int }_{R} {\int }_{ϑ}^{ϑ + 2 β} \vert {Ts}^{[ N ]} ( σ , ν ) \vert d σ d ν} )}^{λ} d σ d ν ) ; \qquad ( 10 )$$
wherein in the equation (10), ϑ represents time; β represents a size of an interval around the time ϑ and λ represents an order of the Renyi entropy, typically set to λ=3.

7. The method for extracting the ZGV features based on the local entropy reconstruction-optimized multi-synchrosqueezing transform algorithm of claim 6, wherein the reconstruction accuracy calculation in the step S5 specifically comprises:
calculating a local reconstruction quality factor
$$R \tilde{Q} {F}_{l}^{β} ( ϑ ) :$$
$$R \tilde{Q} {F}_{l}^{β} ( ϑ ) = 10 {log}_{10} ( \frac{{‖ {x}_{β} ( ϑ ) ‖}^{2}}{{‖ {x}_{β} ( ϑ ) - {\hat{x}}_{β} ( ϑ ) ‖}^{2}} ) ; \qquad ( 11 )$$
wherein x_{β}(ϑ)=[x(ϑ),x(ϑ+1), . . . ,x(ϑ+2β)]\hat{x}_{β}(ϑ)=[\hat{x}(ϑ),\hat{x}(ϑ+1), . . . ,\hat{x}(ϑ+2β)], and \hat{x}(t) represent reconstructed signals obtained via an inverse Fourier transform of TS^{[N]}(t,η).

8. The method for extracting the ZGV features based on the local entropy reconstruction-optimized multi-synchrosqueezing transform algorithm of claim 7, wherein the Bayesian cost function constructed in the step S6 is expressed as follows:
$$g ( l ( ϑ ) ) = 1 - \frac{R \tilde{Q} {F}_{l}^{β} ( ϑ )}{{RE}_{l}^{β} ( ϑ )} . \qquad ( 12 )$$

9. The method for extracting the ZGV features based on the local entropy reconstruction-optimized multi-synchrosqueezing transform algorithm of claim 8, wherein the Bayesian optimization performed on the Bayesian cost function in the step S6 is expressed as follows:
$${l}^{*} ( ϑ ) = arg {min}_{l ∈ [ {l}_{m i n} , {l}_{ma x} ]} g ( l ) ; \qquad ( 13 )$$
wherein in the equation (13), l*(ϑ) represents the globally optimized window function length.

10. The method for extracting the ZGV features based on the local entropy reconstruction-optimized multi-synchrosqueezing transform algorithm of claim 9, wherein in the step S7, the applying the globally optimized window function length from the step S6 to the Gaussian window function to generate the new Gaussian window function is expressed as follows:
$${g}_{L ( m )} ( t ) = \frac{1}{L ( m )} g ( \frac{t}{L ( m )} ) ; \qquad ( 14 )$$
wherein in the equation (14),
$$g ( t ) = \frac{1}{\sqrt{2 π}} {e}^{- \frac{{t}^{2}}{2}} .$$
